(19) United States
(12) Patent Application Publication
(10) Pub. No.: US 2024/0258975 A1
(43) Pub. Date: Aug. 1, 2024

(54) MATCHING NETWORK AND POWER AMPLIFIER INCLUDING THE SAME

(71) Applicant: Samsung Electro-Mechanics Co., Ltd., Suwon-si (KR)

(72) Inventors: Kyujin CHOI, Suwon-si (KR); Seungchul PYO, Suwon-si (KR); Kyung Hee HONG, Suwon-si (KR); Geunyong LEE, Suwon-si (KR); Suyeon HAN, Suwon-si (KR); Yoshiyuki TONAMI, Suwon-si (KR)

(73) Assignee: Samsung Electro-Mechanics Co., Ltd., Suwon-si (KR)

(21) Appl. No.: 18/499,305

(22) Filed: Nov. 1, 2023

(30) Foreign Application Priority Data
Feb. 1, 2023 (KR) 10-2023-0013470

(51) Int. Cl. H03F 1/56; H03F 3/24

(52) U.S. Cl. CPC H03F 1/56; H03F 3/245; H03F 2200/451

(57) ABSTRACT

A matching network is provided. The matching network is configured to perform impedance matching in a power amplifier that amplifies an input radio frequency (RF). The matching network includes a first diode including an anode connected to a node disposed between an input terminal of the matching network and an output terminal of the matching network; and a first stub connected to a cathode of the first diode. A first reverse bias voltage that varies in response to the input RF signal may be applied to the first diode.

### CROSS-REFERENCE TO RELATED APPLICATIONS

This application claims the benefit under 35 USC § 119(a) of Korean Patent Application No. 10-2023-0013470 filed on Feb. 1, 2023, in the Korean Intellectual Property Office, the entire disclosure of which is incorporated herein by reference for all purposes.

### BACKGROUND

### 1. Field

The following description relates to a matching network and a power amplifier including the same.

### 2. Description of the Background

Wireless communication systems apply various digital modulation and demodulation schemes according to the evolution of communication standards. The existing code division multiple access (CDMA) communication system adopts the quadrature phase shift keying (QPSK) method, and the wireless local area network (LAN) following the IEEE communication standard adopts the orthogonal frequency division multiplexing (OFDM) method. Additionally, long term evolution (LTE) and LTE-Advanced, which are recent Third Generation Partnership Project (3GPP) standards, adopt QPSK, quadrature amplitude modulation (QAM), and OFDM schemes. These wireless communication standards adopt a linear modulation method that requires the magnitude or phase of a transmission signal to be maintained during transmission.

A transmitter that is implemented in a wireless communication system may include a power amplifier that amplifies an input radio frequency (RF) signal to increase a transmission distance. Typically, the power amplifier may be implemented in multi-stages, and may be operated in a wide band. In order to implement a multi-stage power amplifier operating in a wide band, the multi-stage power amplifier may include a matching network. The matching network may include a switch that switches a capacitor to provide different impedances depending on a frequency. The use of the switch may be desirous of an additional process and the addition of a logic circuit to control the switch.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a matching network is configured to be disposed in a power amplifier, and is configured to perform impedance matching, the matching network includes a first diode comprising an anode connected to a node disposed between an input terminal of the matching network and an output terminal of the matching network; and a first stub connected to a cathode of the first diode, and wherein a first reverse bias voltage that varies in response to the input RF signal is applied to the first diode.

A first capacitor may be connected between the input terminal and the node; and a second capacitor may be connected between the output terminal and the node.

The first stub may be configured to form a ground node at the cathode of the first diode with respect to an alternating current (AC) signal.

The first stub may be configured to form a floating node at the cathode of the first diode with respect to a direct current (DC) signal.

The first stub may be a λ/4 radial open stub, and the λ may be a wavelength for an operating frequency of the input RF signal.

The matching network may further include a second diode including an anode connected to the node; and a second stub connected to a cathode of the second diode, wherein a second reverse bias voltage that varies in response to the input RF signal is applied to the second diode. The second reverse bias voltage may be equal to the first reverse bias voltage.

The power amplifier may include a first amplifier configured to amplify the input RF signal, and a second amplifier configured to amplify an output RF signal of the first amplifier, and the matching network may be connected between an output terminal of the first amplifier and an input terminal of the second amplifier.

The matching network may be connected to an output terminal of the power amplifier.

In a general aspect, a power amplifier includes a first amplifier configured to amplify an input radio frequency (RF) signal; and a first matching network connected to an output terminal of the first amplifier, wherein the first matching network includes a first input terminal, a first output terminal, a first diode comprising an anode connected to a first node disposed between the first input terminal and the first output terminal and to which a first reverse bias voltage is applied, and a first stub connected to a cathode of the first diode and configured to form a ground node at the cathode of the first diode.

The first matching network may further include a first capacitor connected between the first input terminal and the first node; and a second capacitor connected between the first output terminal and the first node.

The first stub may be configured to form the ground node at the cathode of the first diode with respect to an alternating current (AC) signal, and the first stub may be configured to form a floating node at the cathode of the first diode with respect to a direct current (DC) signal.

The first stub may be a λ/4 radial open stub, and the λ is a wavelength for an operating frequency of the input RF signal.

The power amplifier may further include a second amplifier configured to amplify an output RF signal of the first amplifier; and a second matching network connected to an output terminal of the second amplifier, wherein the first matching network is connected between an output terminal of the first amplifier and an input terminal of the second amplifier, and wherein the second matching network includes a second input terminal, a second output terminal, a second diode comprising an anode connected to a second node disposed between the second input terminal and the second output terminal and to which a second reverse bias voltage is applied, and a second stub connected to a cathode of the second diode and forming a ground node at the cathode of the second diode.

In a general aspect, a power amplifier includes a matching network, wherein the matching network includes a first diode connected to a first node between an input terminal of the matching network and an output terminal of the matching network, a second diode connected to a second node between the input terminal of the matching network and the output terminal of the matching network, a first radial open stub connected to a cathode of the first diode, and a second radial open stub connected to a cathode of the second diode, wherein the first radial open stub and the second radial open stub are configured to form a ground node at the cathode of the first diode and the cathode of the second diode for an alternating current (AC) signal, and form a floating node at the cathode of the first diode and the cathode of the second diode for a direct current (DC) signal.

The first diode and the second diode may be variable capacitance diodes.

The matching network may further include a variable voltage generator configured to generate a reverse voltage, and apply the generated reverse voltage to respective ends of the first diode and the second diode.

The matching network may further include a first capacitor connected to an input terminal of the matching network, and a second capacitor connected to an output terminal of the matching network.

The matching network may be connected to an output terminal of an amplifier.

Other features and examples will be apparent from the following detailed description, the drawings, and the claims.

### BRIEF DESCRIPTION OF DRAWINGS

FIG. 1 illustrates an example power amplifier, in accordance with one or more embodiments.

FIG. 2 illustrates a circuit diagram of an example matching network, in accordance with one or more embodiments.

FIG. 3 illustrates a graph of a relationship between a reverse bias voltage (V_{R}) and a capacitance value.

FIG. 4 illustrates an equivalent circuit of a matching network of FIG. 3.

FIG. 5 illustrates a circuit of an example matching network, in accordance with one or more embodiments.

FIG. 6 illustrates an example matching network, in accordance with one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning, e.g., the phrasing “in one example” has a same meaning as “in one embodiment”, and “one or more examples” has a same meaning as “in one or more embodiments.”

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

One or more examples may provide a matching network having a simple structure.

One or more examples may provide a variable capacitance through a diode, thereby providing a simple and small-area matching network.

One or more examples may provide a variable capacitance through a diode, thereby providing a matching network that is continuous and has many capacitance values.

One or more examples may prevent resonance from occurring by forming a ground node at a cathode of a diode through a stub.

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile Communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

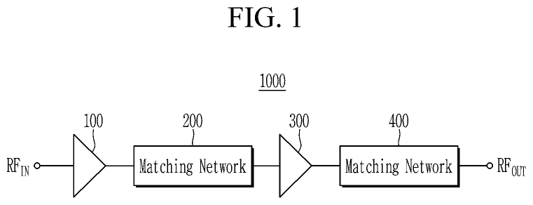

FIG. 1 illustrates an example power amplifier 1000, in accordance with one or more embodiments.

As illustrated in FIG. 1, an example power amplifier 1000, in accordance with one or more embodiments, may include a first amplifier 100, a first matching network 200, a second amplifier 300, and a second matching network 400.

The first amplifier 100 may amplify power of an RF signal inputted to an input terminal thereof, and then output the RF signal to an output terminal thereof. The first amplifier 100 may be a driver stage as a first stage amplifier. In FIG. 1, the input RF signal inputted to the input terminal of the first amplifier 100 is indicated as ‘RF_{IN}’. In an example, the first amplifier 100 may be implemented as a power transistor. The input terminal of the first amplifier 100 may be a base of a power transistor, and the output terminal of the first amplifier 100 may be a collector of the power transistor. An emitter of the power transistor may be connected to the ground, and a resistor may be additionally connected between the emitter of the power transistor and the ground. Additionally, the collector of the power transistor may be connected to a power source voltage, and the power transistor may be operated by the power source voltage. In an example, the collector of the power transistor may be connected to the power source voltage through an inductor that performs an RF choke operation.

The power transistor included in the first amplifier 100 may be realized as various transistors such as, but not limited to, a heterojunction bipolar transistor (HBT), a bipolar junction transistor (BJT), and an insulated gate bipolar transistor (IGBT), as only examples.

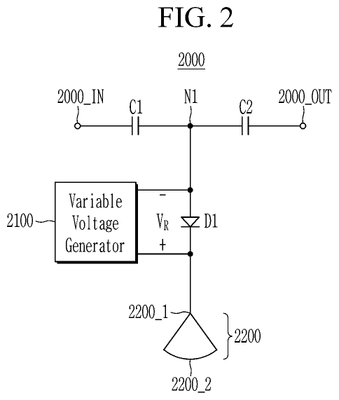

The first matching network 200 may be connected between the output terminal of the first amplifier 100 and the input terminal of the second amplifier 300. The first matching network 200 performs impedance matching between the respective first and second amplifiers 100 and 300. In an example, the first matching network 200 may be an interstage matching network. The first matching network 200 may provide a variable impedance according to a frequency of an input RF signal RF_{IN}. The first matching network 200, in accordance with one or more embodiments, has a simple structure that may not use a switch, which will be described in detail with reference to FIG. 2 below.

The second amplifier 300 may amplify power of an RF signal inputted to an input terminal thereof, and then output the RF signal to an output terminal thereof. That is, the second amplifier 300 amplifies the RF signal that has passed through the first matching network 200 once more. The second amplifier 300 may be a power stage as a second stage amplifier. The second amplifier 300 may be implemented as a power transistor. The input terminal of the second amplifier 300 may be a base of a power transistor, and the output terminal of the second amplifier 300 may be a collector of the power transistor. An emitter of the power transistor may be connected to the ground, and a resistor may be additionally connected between the emitter of the power transistor and the ground. Additionally, the collector of the power transistor may be connected to a power source voltage, and the power transistor may be operated by the power source voltage. In an example, the collector of the power transistor may be connected to the power source voltage through an inductor that performs an RF choke operation.

The power transistor included in the second amplifier 300 may be realized as various transistors such as, but not limited to, a heterojunction bipolar transistor (HBT), a bipolar junction transistor (BJT), and an insulated gate bipolar transistor (IGBT), as only examples.

The second matching network 400 may be connected to the output terminal of the second amplifier 300. The second matching network 400 may perform impedance matching between an output signal of the second amplifier 300 and a load. The second matching network 400 may be a load matching network.

In FIG. 1, the RF signal that is finally outputted from the power amplifier 1000 is indicated as ‘RF_{OUT}’. The second matching network 400 may provide a variable impedance according to a frequency of the input RF signal RF_{IN}. The second matching network 400, in accordance with one or more embodiments, may have a simple structure that may not use a switch, which will be described in detail with reference to FIG. 2 below.

FIG. 2 illustrates a circuit diagram of an example matching network 2000, in accordance with one or more embodiments.

The example matching network 2000 of FIG. 2 may be the matching network 200 of FIG. 1 or the matching network 400 of FIG. 1. That is, the matching network 200 of FIG. 1 may be implemented in a similar manner as the matching network 2000 of FIG. 2, and the matching network 400 of FIG. 1 may be implemented in a similar manner as the matching network 2000 of FIG. 2.

As illustrated in FIG. 2, the matching network 2000, in accordance with one or more embodiments, may include a capacitor C1, a capacitor C2, a diode D1, a variable voltage generator 2100, and a stub 2200.

The matching network 2000 may have an input terminal 2000_IN and an output terminal 2000_OUT. In an example, the input terminal 2000_IN may be connected to the output terminal of the first amplifier 100, and the output terminal 2000_OUT may be connected to the input terminal of the second amplifier 300. In another example, the input terminal 2000_IN may be connected to the output terminal of the second amplifier 300, and an output RF signal RF_{OUT} may be output from the output terminal 2000_OUT.

A first end of the capacitor C1 may be connected to the input terminal 2000_IN, and a second end of the capacitor C1 may be connected to a first end of the capacitor C2. The second end of the capacitor C2 may be connected to the output terminal 2000_OUT. In FIG. 2, a node at which the capacitor C1 and the capacitor C2 are connected to each other is indicated as a ‘node N1’.

An anode of the diode D1 may be connected to the second end of the capacitor C1 and the first end of the capacitor C2. That is, the anode of the diode D1 may be connected to the node N1. Additionally, a cathode of the diode D1 is connected to the stub 2200.

The variable voltage generator 2100 may generate a reverse bias voltage V_{R} that varies according to the frequency of the input RF signal RF_{IN}. The reverse bias voltage V_{R} generated by the variable voltage generator 2100 may be applied to respective ends of the diode D1. In an example, the cathode of the diode D1 may be biased at a higher potential than a potential of the anode of the diode D1 based on the reverse bias voltage V_{R}. That is, the diode D1 may be reverse-biased. A method of generating a variable voltage by the variable voltage generator 2100 may be known to those skilled in the art. Accordingly, a detailed description thereof will be omitted.

In an example, since the capacitance value of the diode D1 varies in response to the reverse bias voltage V_{R}, the diode D1 may be a varactor diode. The diode D1 may be implemented in the form of a P-N junction. When the reverse bias voltage V_{R} is applied to the diode D1, a depletion layer is formed between the P-N junction. In an example, when the reverse bias voltage is varied, a thickness of the depletion layer is varied. Accordingly, the diode D1 may have a variable capacitance value.

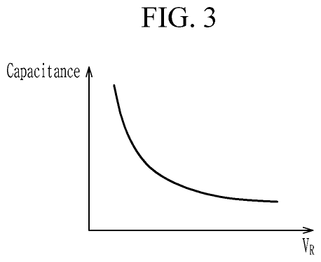

FIG. 3 illustrates a graph of a relationship between a reverse bias voltage (V_{R}) and a capacitance value.

As illustrated in FIG. 3, the capacitance value may be varied depending on the reverse bias voltage V_{R}. As the reverse bias voltage V_{R} increases, the capacitance value may decrease. As described above, by implementing the variable capacitance value through the diode D1, the matching network 2000 according to the embodiment may be implemented more conveniently and with a smaller area than when using a switch. Additionally, the matching network 2000, in accordance with one or more embodiments, may have a continuous capacitance value through adjustment of the reverse bias voltage V_{R}. In contrast, a typical method of adjusting the variable capacitance value through a switch has discrete capacitance values. That is, the matching network 2000, in accordance with one or more embodiments, may have more continuous capacitance values than the typical method.

The stub 2200 may be connected to the cathode of the diode D1. The stub 2200 may be a radial open stub. In an example, the stub 2200 may be a λ/4 radial open stub. In an example, λ denotes a wavelength for an operating frequency of the input RF signal RF_{IN}.

As illustrated in FIG. 2, the stub 2200 may include a short circuit node 2200_1 and an open circuit node 2200_2. In terms of alternating current (AC) (for an AC signal), impedance seen at a distance λ/4 away from the open node 22002 (that is, the short circuit node 2200_1) may form a short impedance node at an operating frequency of the input RF signal RF_{IN}. In terms of AC (for an AC signal), a short circuit impedance node means a ground node, so the stub 2200 may form (or provide) a ground node at the cathode of the diode D1. Additionally, in terms of direct current (DC) (for a DC signal), the reverse bias voltage VR may be applied to the entire area of the stub 2200. That is, in terms of DC, the stub 2200 may form (or provide) a floating node at the cathode of the diode D1. A specific configuration of the stub 2200 may be known to those skilled in the art, so a detailed description thereof will be omitted.

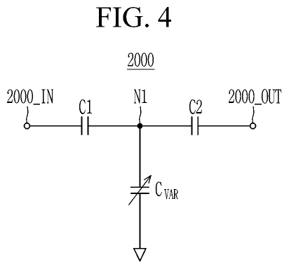

FIG. 4 illustrates an equivalent circuit of the matching network 2000 of FIG. 3.

As described in FIG. 2, since the diode D1 may have the variable capacitance value corresponding to the reverse bias voltage V_{R}, the diode D1 may be equalized to a variable capacitor C_{VAR}. Additionally, in terms of AC (for an AC signal), since the stub 2200 forms the ground node at the cathode of the diode D1, the stub 2200 may be equalized to the ground. Accordingly, the matching network 200 may have various impedance values based on a combination of the capacitor C1, the capacitor C2, and the variable capacitor C_{VAR}.

As described above, the matching network 2000, in accordance with one or more embodiments, may implement the stub 2200 without using a physical ground in forming the ground in an AC manner (with respect to an AC signal). In the example of using the physical ground, an inductance may be formed at the physical ground. Accordingly, a problem occurs in which resonance occurs between the physical ground and the capacitor. In contrast, since the matching network 2000, in accordance with one or more embodiments, forms the ground node by using the stub 2200, it is possible to prevent resonance from occurring.

In FIG. 2, the capacitor C1 and the capacitor C2 may prevent the reverse bias voltage VR from being introduced into the amplifier 100 and the amplifier 300. Considering the frequency characteristics of the capacitor, the capacitor may have a high impedance value at DC. Accordingly, the capacitor C1 may block the reverse bias voltage V_{R} from flowing into the input terminal 2000_IN, and the capacitor C2 may block the reverse bias voltage V_{R} from flowing into the output terminal 2000_OUT.

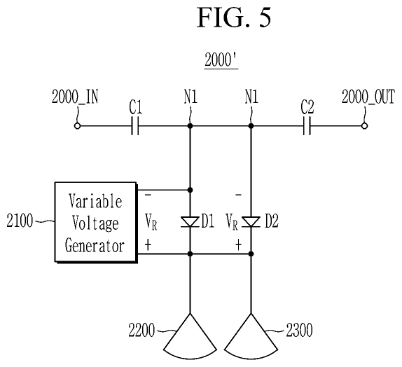

FIG. 5 illustrates a circuit of an example matching network 2000′, in accordance with one or more embodiments.

In an example, the matching network 2000′ of FIG. 5 may be the first matching network 200 of FIG. 1 or the second matching network 400 of FIG. 1. That is, the first matching network 200 of FIG. 1 may be implemented in a manner that is similar to the matching network 2000′ of FIG. 5, and the second matching network 400 of FIG. 1 may be implemented in a manner that is similar to the matching network 2000′ of FIG. 5.

The matching network 2000′ of FIG. 5 may be similar to the matching network 2000 of FIG. 2 except that a diode D2 and a stub 2300 are added. Accordingly, redundant descriptions will be omitted below.

An anode of the diode D2 may be connected to the second end of the capacitor C1 and the first end of the capacitor C2. That is, the anode of the diode D2 may be connected to the node N1. Additionally, a cathode of the diode D2 is connected to the stub 2300.

Referring to FIG. 5, in an example, the second diode D2 may include an anode that is connected to a second node disposed between the second end of the capacitor C1 and the first end of the capacitor C2, and to which a second reverse bias voltage is applied.

The variable voltage generator 2100 may generate the reverse bias voltage VR and apply the generated reverse bias voltage VR to respective ends of the diode D2 as well as respective ends of the diode D1.

The diode D2 may have a variable capacitance value corresponding to the reverse bias voltage VR, similar to the diode D1.

The stub 2300 may be connected to the cathode of the diode D2. In an example, the stub 2300 may be a λ/4 radial open stub. In terms of AC (for an AC signal), the stub 2300 may form (or provide) a ground node at the cathode of the diode D2. Additionally, in terms of DC (for a DC signal), the stub 2300 may form (or provide) a floating node at the cathode of the diode D2.

The matching network 2000′ of FIG. 5 may include two diodes D1 and D2 having variable capacitance values according to the frequency of the input RF signal RF_{IN}. Accordingly, the matching network 2000′ of FIG. 5 may be able to adjust more capacitance values than the matching network 2000 of FIG. 2.

In an example, in the matching network 2000′ of FIG. 5, a diode and a stub having the same structure as the diode D2 and the stub 2300 are additionally connected, so that the adjustment of the capacitance value may be extended.

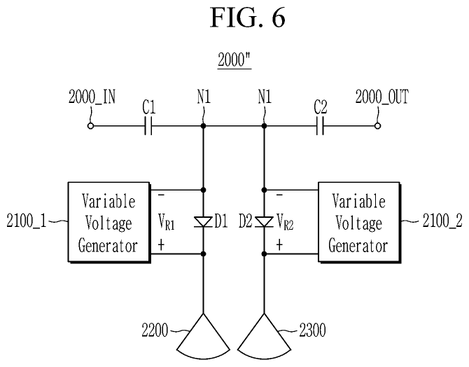

FIG. 6 illustrates a matching network 2000″, in accordance with one or more embodiments.

The example matching network 2000″ of FIG. 6 may be similar to the matching network 2000′ of FIG. 5 except that a variable voltage generator 2100_2 is added. The example matching network 2000″ of FIG. 6 may be the first matching network 200 of FIG. 1 or the second matching network 400 of FIG. 1. That is, the first matching network 200 of FIG. 1 may be implemented in a manner that is similar to the matching network 2000″ of FIG. 6, and the second matching network 400 of FIG. 1 may be implemented in a manner that is similar to the matching network 2000″ of FIG. 6.

Referring to FIG. 6, in an example, the second diode D2 may include an anode that is connected to a second node disposed between the second end of the capacitor C1 and the first end of the capacitor C2, and to which a second reverse bias voltage is applied.

The variable voltage generator 2100_1 may generate a reverse bias voltage V_{R1}, and may apply the generated reverse bias voltage V_{R1} to respective ends of the diode D1. Additionally, the variable voltage generator 2100_2 may generate a reverse bias voltage V_{R2}, and may apply the generated reverse bias voltage V_{R2} to respective ends of the diode D2.

The diode D1 may have a variable capacitance value corresponding to the reverse bias voltage V_{R1}. Additionally, the diode D2 may have a variable capacitance value corresponding to the reverse bias voltage V_{R2}. That is, since the capacitance values of the diode D1 and the diode D2 are independently adjusted, the matching network 2000″ of FIG. 6 may have more impedance values than the matching network 2000′ of FIG. 5.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A matching network configured to be disposed in a power amplifier, and configured to perform impedance matching, the matching network comprising:
a first diode comprising an anode connected to a node disposed between an input terminal of the matching network and an output terminal of the matching network; and
a first stub connected to a cathode of the first diode,
wherein a first reverse bias voltage that varies in response to an input radio frequency (RF) signal is applied to the first diode.

2. The matching network of claim 1, further comprising:
a first capacitor connected between the input terminal and the node; and
a second capacitor connected between the output terminal and the node.

3. The matching network of claim 1, wherein:
the first stub is configured to form a ground node at the cathode of the first diode with respect to an alternating current (AC) signal.

4. The matching network of claim 3, wherein:
the first stub is configured to form a floating node at the cathode of the first diode with respect to a direct current (DC) signal.

5. The matching network of claim 1, wherein:
the first stub is a λ/4 radial open stub, and the λ is a wavelength for an operating frequency of the input RF signal.

6. The matching network of claim 1, further comprising:
a second diode comprising an anode connected to the node; and
a second stub connected to a cathode of the second diode,
wherein a second reverse bias voltage that varies in response to the input RF signal is applied to the second diode.

7. The matching network of claim 6, wherein:
the second reverse bias voltage is equal to the first reverse bias voltage.

8. The matching network of claim 1, wherein:
the power amplifier comprises a first amplifier configured to amplify the input RF signal, and a second amplifier configured to amplify an output RF signal of the first amplifier, and
the matching network is connected between an output terminal of the first amplifier and an input terminal of the second amplifier.

9. The matching network of claim 1, wherein:
the matching network is connected to an output terminal of the power amplifier.

10. A power amplifier, comprising:
a first amplifier configured to amplify an input radio frequency (RF) signal; and
a first matching network connected to an output terminal of the first amplifier,
wherein the first matching network comprises:
a first input terminal,
a first output terminal,
a first diode comprising an anode connected to a first node disposed between the first input terminal and the first output terminal and to which a first reverse bias voltage is applied, and
a first stub connected to a cathode of the first diode and configured to form a ground node at the cathode of the first diode.

11. The power amplifier of claim 10, wherein:
the first matching network further comprises:
a first capacitor connected between the first input terminal and the first node; and
a second capacitor connected between the first output terminal and the first node.

12. The power amplifier of claim 10, wherein:
the first stub is configured to form the ground node at the cathode of the first diode with respect to an alternating current (AC) signal, and
the first stub is configured to form a floating node at the cathode of the first diode with respect to a direct current (DC) signal.

13. The power amplifier of claim 10, wherein:
the first stub is a λ/4 radial open stub, and the λ is a wavelength for an operating frequency of the input RF signal.

14. The power amplifier of claim 10, further comprising:
a second amplifier configured to amplify an output RF signal of the first amplifier; and
a second matching network connected to an output terminal of the second amplifier,
wherein the first matching network is connected between an output terminal of the first amplifier and an input terminal of the second amplifier, and
wherein the second matching network comprises:
a second input terminal,
a second output terminal,
a second diode comprising an anode connected to a second node disposed between the second input terminal and the second output terminal and to which a second reverse bias voltage is applied, and
a second stub connected to a cathode of the second diode and forming a ground node at the cathode of the second diode.

15. A power amplifier, comprising:
a matching network,
wherein the matching network comprises:
a first diode connected to a first node between an input terminal of the matching network and an output terminal of the matching network,
a second diode connected to a second node between the input terminal of the matching network and the output terminal of the matching network,
a first radial open stub connected to a cathode of the first diode, and
a second radial open stub connected to a cathode of the second diode,
wherein the first radial open stub and the second radial open stub are configured to form a ground node at the cathode of the first diode and the cathode of the second diode for an alternating current (AC) signal, and form a floating node at the cathode of the first diode and the cathode of the second diode for a direct current (DC) signal.

16. The power amplifier of claim 15, wherein the first diode and the second diode are variable capacitance diodes.

17. The power amplifier of claim 15, wherein the matching network further comprises a variable voltage generator configured to generate a reverse voltage, and apply the generated reverse voltage to respective ends of the first diode and the second diode.

18. The power amplifier of claim 15, wherein the matching network further comprises a first capacitor connected to an input terminal of the matching network, and a second capacitor connected to an output terminal of the matching network.

19. The power amplifier of claim 15, wherein the matching network is connected to an output terminal of an amplifier.
